(19) United States
(12) Patent Application Publication
(10) Pub. No.: US 2024/0162674 A1
(43) Pub. Date: May 16, 2024

(54) SELF-REFERENCING ULTRAFAST LASER SYSTEM WITH PULSE SHAPING

(71) Applicant: Board of Trustees of Michigan State University, East Lansing, MI (US)

(72) Inventors: Marcos DANTUS, Okemos, MI (US); Jacob Anthony STAMM, Howell, MI (US); Jorge Guillermo BENEL MOGROVEJO, Lima (PE)

(73) Assignee: Board of Trustees of Michigan State University, East Lansing, MI (US)

(21) Appl. No.: 18/278,910

(22) PCT Filed: Mar. 3, 2022
(86) PCT No.: PCT/US2022/018636

§ 371 Date: Aug. 25, 2023

Related U.S. Application Data
(60) Provisional application No. 63/156,626, filed on Mar. 4, 2021.

(51) Int. Cl. H01S 3/00

(52) U.S. Cl. CPC H01S 3/0057; H01S 3/0014; H01S 3/0085

(57) ABSTRACT

A laser system employs a laser, a pulse shaper, and a controller configured to measure phase variations on pre-compressed laser pulses. In another aspect, a laser apparatus and method include programmed software instructions which measure phase variations of ultrafast laser pulses. A further aspect of the present system and method includes a laser, an active pulse shaper, and a controller which measure and/or correct distortions of laser pulses with π/2 scanning.

### CROSS-REFERENCE TO RELATED APPLICATIONS

The present application claims priority to U.S. provisional patent application Ser. No. 63/156,626 filed on Mar. 4, 2021, which is incorporated by reference herein.

### GOVERNMENT FUNDING

This invention was made with government support under DE-SC0002325 awarded by the U.S. Department of Energy, and under CHE1836498 awarded by the National Science Foundation. The government has certain rights in the invention.

### BACKGROUND

The present disclosure relates generally to a laser system and, more particularly, to a method and apparatus for self-referenced characterization and phase control of ultrafast laser pulses using pulse shaping.

Ultrashort laser pulses have recently seen widespread use. A spectral phase within a bandwidth of the pulse determines their duration and performance, thereby needing external methods to measure and control the phase. Multiple conventional pulse characterization methods have been employed in the past. The accuracy with which the phase is measured and controlled by the different methods impacts the reproducibility of experimental results, optimizes the peak intensity of the pulses, and if very high accuracy is achieved, allows the pulses to be used in metrological applications such as the generation of pulse trains. Traditional methods include Frequency-Resolved Optical Gating (“FROG”), which involves complicated retrieval, and Spectral Phase Interferometry for Direct Electric-Field Reconstruction (“SPIDER”), which involves a complicated optical setup.

A more recent pulse shaper-based approach is the Multiphoton Intrapulse Interference Phase Scan procedure and software (MIIPS®), which scans a known phase such as chirp or a cosine function to measure the unknown spectral phase of the output pulses. Such a MIIPS® system is disclosed in U.S. Pat. No. 8,675,699, entitled “Laser Pulse Synthesis System,” U.S. Pat. No. 8,633,437, entitled “Ultra-Fast Laser System,” U.S. Pat. No. 8,630,322, entitled “Laser System For Output Manipulation,” U.S. Pat. No. 8,311,069, entitled “Direct Ultrashort Laser System,” U.S. Pat. No. 8,300,669, entitled “Control System And Apparatus For Use With Ultra-Fast Laser,” U.S. Pat. No. 8,208,504, entitled “Laser Pulse Shaping System,” and U.S. Pat. No. 7,609,731, entitled “Laser System Using Ultra-Short Laser Pulses,” all of which were invented or co-invented by M. Dantus, and are incorporated by reference herein. Furthermore, U.S. Pat. No. 7,567,596, entitled “Control System and Apparatus for use with Ultra-Fast Laser,” to M. Dantus, et al., discloses a binary phase shaping system, and is also incorporated by reference herein.

Accurate measurement of the spectral phase of ultrafast pulses is paramount for pulse characterization, such that benchmarking against materials with known group velocity dispersion (“GVD”) has become the norm. Traditional pulse characterization methods are now approaching accuracies that rival measurements obtained by spectral interferometry. Nevertheless, the use of ultrafast laser pulses in communications, quantum computing, and cryptography will require even tight control of the spectral phase for low-noise output. As ultrafast lasers evolve, their metrology must evolve as well. Therefore, additional accuracy improvements are desired and correction of the spectral phase to sub-radian accuracy is becoming a more important goal as ultrafast lasers see wider use in the various fields of science and industry.

### SUMMARY

In accordance with the present invention, a laser system employs a laser, a pulse shaper, and a controller configured to measure phase variations on pre-compressed laser pulses. In another aspect, a laser apparatus and method include programmed software instructions which measure phase variations of ultrafast laser pulses. A further aspect of the present system and method includes a laser, an active pulse shaper, and a controller which measure and/or correct distortions of laser pulses with π/2 scanning. Yet another aspect measures chirp and third-order dispersion of laser pulses each having a duration less than 1000 femtoseconds with <10 milliradian precision, including arbitrary phases. Still another aspect includes a system and method including emitting laser pulses each having a duration less than 1000 femtoseconds, the pulses having second or greater order dispersion; shaping the laser pulses; and measuring single-digit milliradian phase variations on the pulses by a programmable controller with the use of π/2 scan of a spectral phase of at least one of the laser pulses, regardless of whether the pulse is asymmetric.

The present method and system are advantageous over prior devices. For example, the present method and system provide greater precision and accuracy than conventional procedures, and in an easy-to-use and fast, automatic manner. Beneficially, the present laser system and method scan a π/2 and a −π/2 phase step across a spectrum of a laser pulse to reveal small spectral phase deformations, which is at least one order of magnitude more sensitive the phase deformations than the previous MIIPS® method. For example, the present system and method use a pulse shaper to scan a sharp phase step to reveal very small residual amounts of spectral dispersion such as, but not limited to chirp and third-order dispersion. When this method is compared to benchmarks, the accuracy estimated by a group delay dispersion measurement of fused silica is within 0.02 fs², and the precision is estimated to be 1 fs², by way of a non-limiting example. The present system is also advantageous over conventional binary phase shaping in that, for conventional binary shaping, 0 and π values are used to compress but not measure the pulse, however, the present system finds that half integer values of π are most sensitive for pulse measurement and that integer values of π are not sensitive for pulse measurement. Nevertheless, for compression in the present system, any value of phase can be used without restriction whereby no diffraction loss is suffered as contrasted to the conventional binary compression situation. Additional advantages and benefits of the present method and system will become apparent from the following description and appended claims taken in conjunction with the accompanying drawings.

### BRIEF DESCRIPTION OF THE DRAWINGS

FIG. 1 is a diagrammatic view showing preferred hardware used with the present laser system.

FIG. 2 is a graph showing the spectrum of a femtosecond laser pulse and a phase step using the present laser system.

FIG. 3 is a graph showing the the same spectrum and phase step shown in FIG. 2 on a wavelength scale using the present laser system.

FIG. 4 is a graph showing the effect of a phase step on the second harmonic spectrum of a femtosecond laser pulse using the present laser system.

FIG. 5 is a graph showing the same effect of a phase step on the second harmonic spectrum of a femtosecond laser shown in FIG. 4 on a wavelength scale using the present laser system.

FIG. 6 is a graph showing a second harmonic intensity contour plot resulting from scanning a π/2 phase step using the present laser system.

FIG. 7 is a graph showing a second harmonic intensity contour plot resulting from scanning a −π/2 phase step using the present laser system.

FIG. 8 is a graph showing a difference contour plot for pulses with chirp using the present laser system.

FIG. 9 is a graph showing a difference contour plot for pulses with TOD using the present laser system.

FIG. 10 is a graph showing a difference between SH intensities using the present laser system.

FIG. 11 is a graph showing the dependence of slopes as a function of reduced chirp using the present laser system.

FIG. 12 is a graph showing the dependence of slopes as a function of reduced TOD using the present laser system.

FIG. 13 is a graph showing the expected characterization of pulses after compression using the present laser system.

FIG. 14 is a graph showing the expected characterization of pulses after compression using the present laser system.

FIG. 15 is a graph showing expected values of slopes as a function of chirp using the present laser system.

FIG. 16 is a graph showing expected values of slopes as a function of TOD using the present laser system.

FIG. 17 is a graph showing estimated performance for chirp and TOD measurements using the present laser system.

FIGS. 18A-C are flowcharts showing programmed computer software instructions used for initial calibration and compression in the present laser system.

FIG. 19 is a flowchart showing programmed computer software instructions used for precompression in the present laser system.

FIG. 20 is a flowchart showing programmed computer software instructions used for chirp measurement in the present laser system.

FIG. 21 is a flowchart showing programmed computer software instructions used for TOD measurement in the present laser system.

FIG. 22 is a flowchart showing programmed computer software instructions used for arbitrary phase measurement in the present laser system.

FIGS. 23A and B are flowcharts showing programmed computer software instructions used for arbitrary phase measurement and compression in the present laser system.

### DETAILED DESCRIPTION

Referring to FIG. 1, a preferred laser system and apparatus 31 employs a regenerative Ti:Sapphire, femtosecond seed laser 33, including an amplifier and an oscillator, which emits multiple laser pulses 35. System 31 further includes first a set of mirrors 37, a pulse shaper 39, a focusing lens 41, a second harmonic crystal 43, and a spectrometer detector 45. Shaper 39 includes a programmable spatial light modulator (“SLM”) 51, which is actively and programmably adaptive, and controlled and varied by a computer controller 53 connected thereto. Shaper further includes a grating 55 and a parabolic curved mirror 57. The duration of each pulse 35 is preferably less than 1000 fs and more preferably equal to or less than 15 fs.

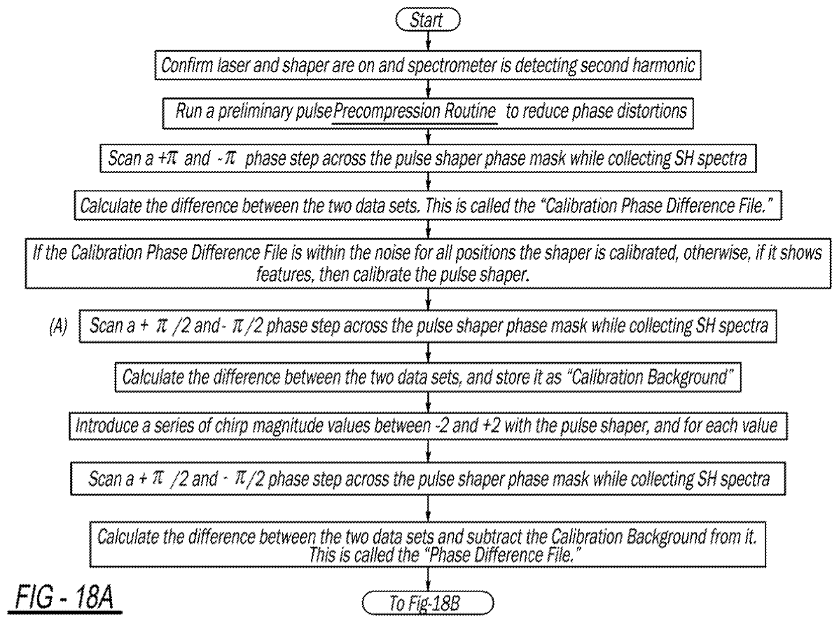

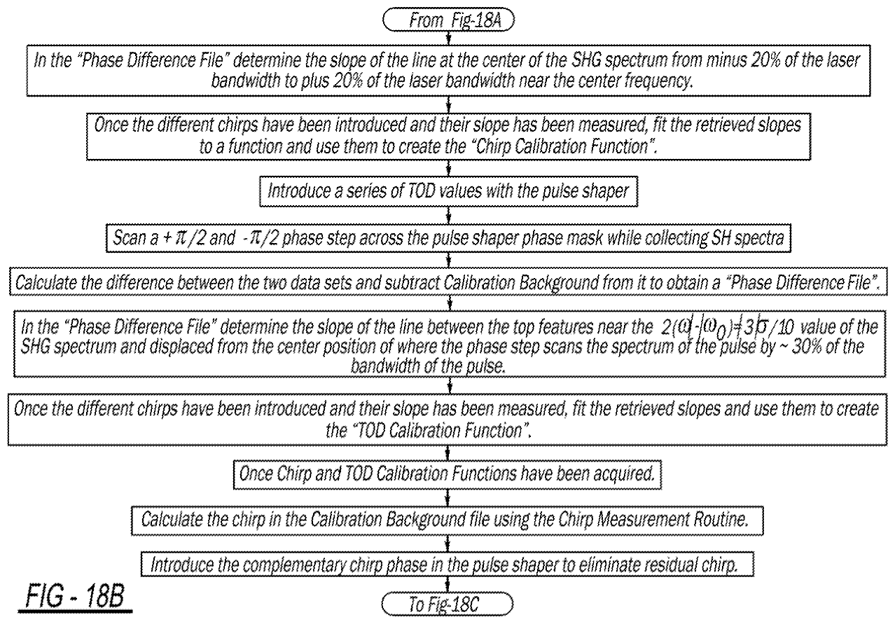

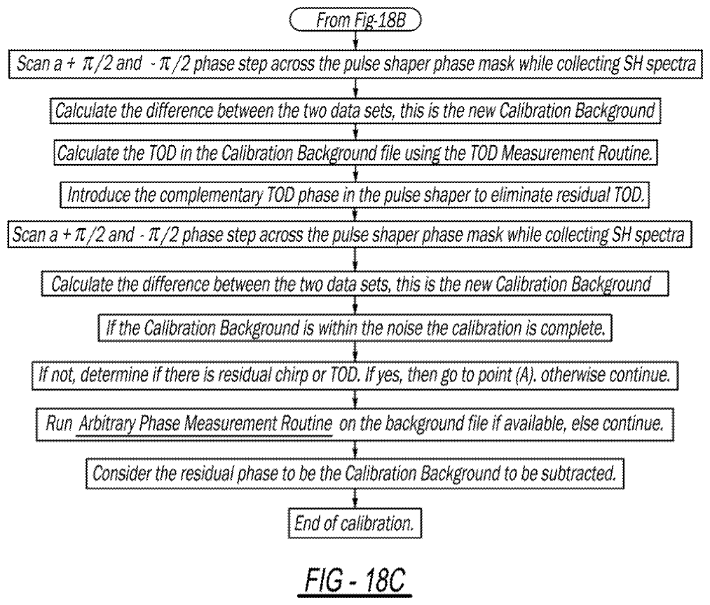

Software flow diagrams used in the present laser system are shown in FIGS. 18A-23B. The software includes coded instructions, in a non-transient form, programmed in memory of computer controller 53 (see FIG. 1) which is executed by its microprocessor or other electronics and/or circuitry therein. The software instructions and controller automatically and/or manually control laser 33 and pulse shaper 39, and receive sensed pulse signals from detector 45.

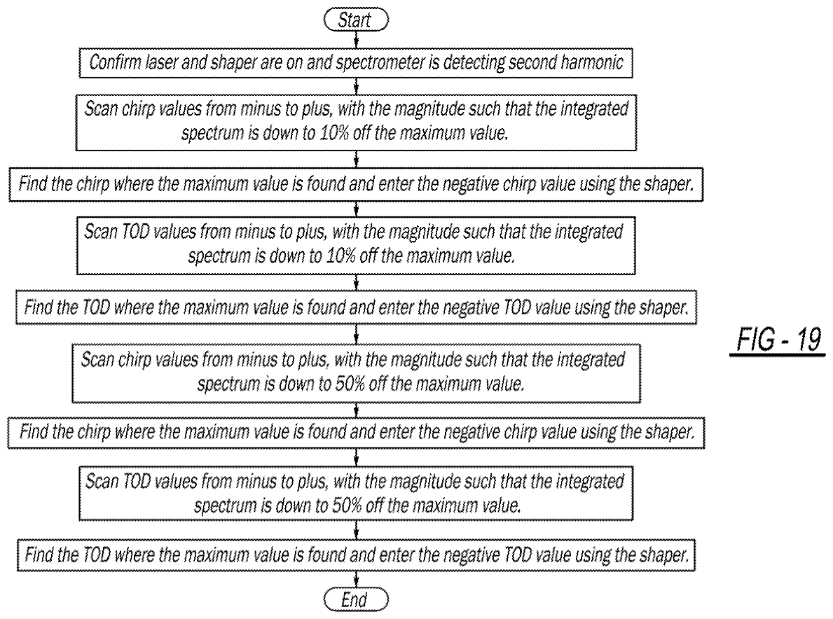

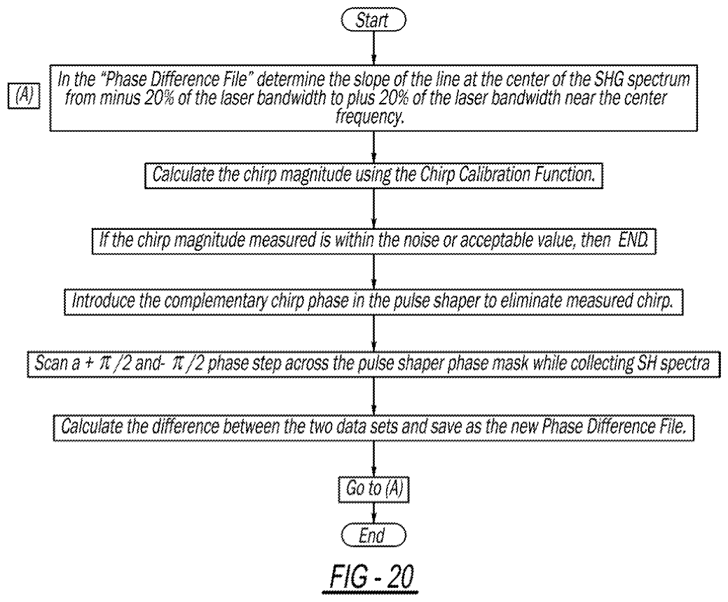

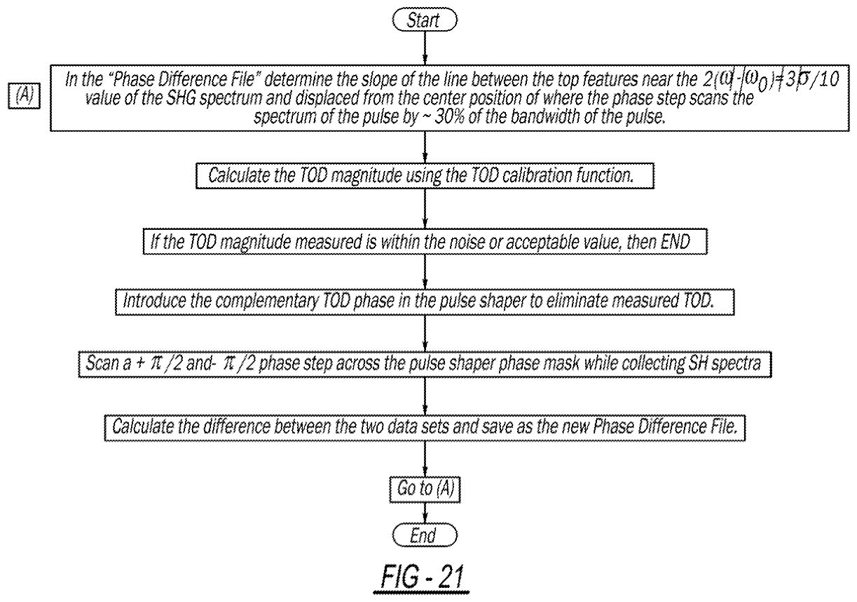

More specifically, FIGS. 18A-C depict computer software instructions and steps used for initial calibration and compression while those of FIG. 19 are used for precompression as an alternative to the MIIPS® procedures. The logic flowchart of FIG. 20 illustrates programmed computer software instructions used for chirp measurement in the present laser system. Similarly, FIG. 21 shows programmed computer software instructions and steps used for third-order dispersion (“TOD”) measurement.

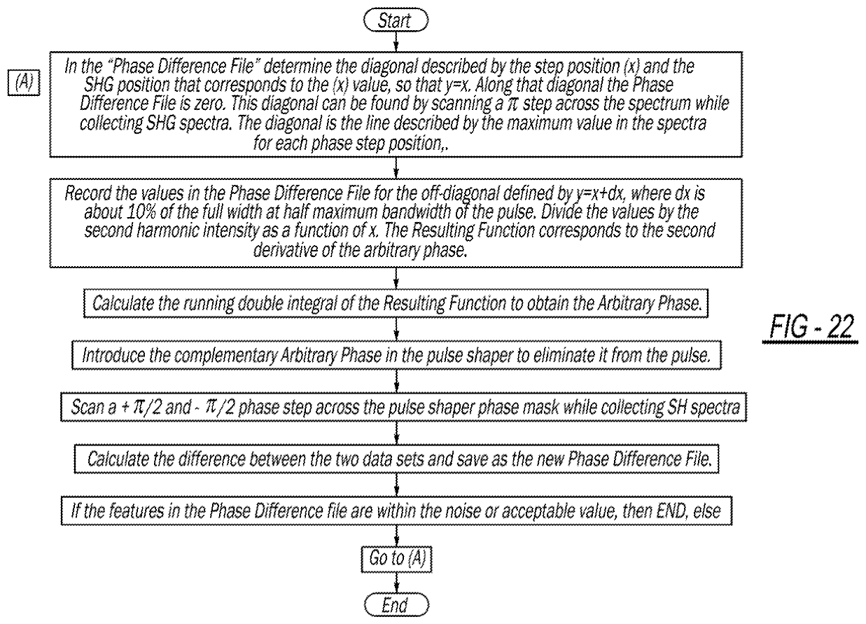

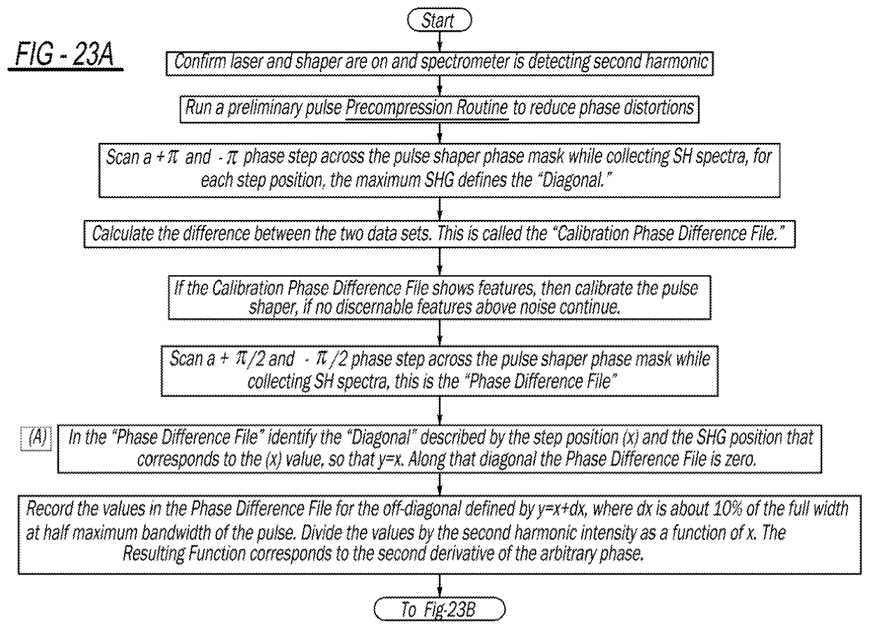

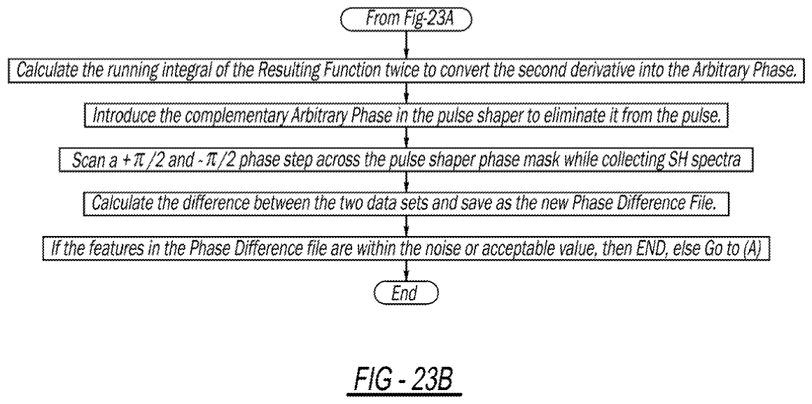

It is noteworthy that FIG. 22 is a logic flowchart showing programmed computer software instructions used for arbitrary phase measurement that is usable with other software instruction routines disclosed herein. Moreover, FIGS. 23A and B illustrate programmed computer software instructions used for arbitrary phase measurement and compression, which therefore only needs the precompression software program. The software programs and steps disclosed herein beneficially allow for automated control and measuring by the present laser system.

The present laser system measures small amounts of chirp and TOD that cannot be measured or corrected by traditional procedures but can affect the reproducibility of experimental results or processes, for example, molecular fragmentation in strong fields. Chirp and TOD are quantified and their magnitudes are given by β₂, and β₃ in the following expression:

$$φ ( ω ) = \frac{{β}_{2}}{2 !} {( ω - {ω}_{0} )}^{2} + \frac{{β}_{3}}{3 !} {( ω - {ω}_{0} )}^{3} , \qquad ( 1 )$$

where ω₀ is the center frequency of the spectrum. Linear and constant terms are ignored as they give rise to the carrier-envelope phase and the group delay. Moreover, for the first part of the theory, it is assumed that the pulses are Gaussian:

\tilde{E}(ω)≡\sqrt{S(ω)}exp{−iφ(ω)} (2)

where

S(ω)=exp{−g²(ω−ω₀)²/σ_{f}²} (3)

is the spectrum of the pulse, with a bandwidth σ_{f} full width at half maximum (FWHM), and g=2\sqrt{ln2}. The pulse duration FWHM, τ_{f}, is related to its bandwidth by the time-bandwidth product (TBP) σ_{f}τ_{f}≥g², with equality when the pulse is transform-limited (“TL”). Since the bandwidth is in angular frequency, dividing by 2π provides factor 0.44127 used to determine if the TBP of a Gaussian pulse is near TL. The expression for the intensity of the TL pulse in the time domain is given by:

I_{TL}(t)=exp{−g²(t/τ_{f})²}. (4)

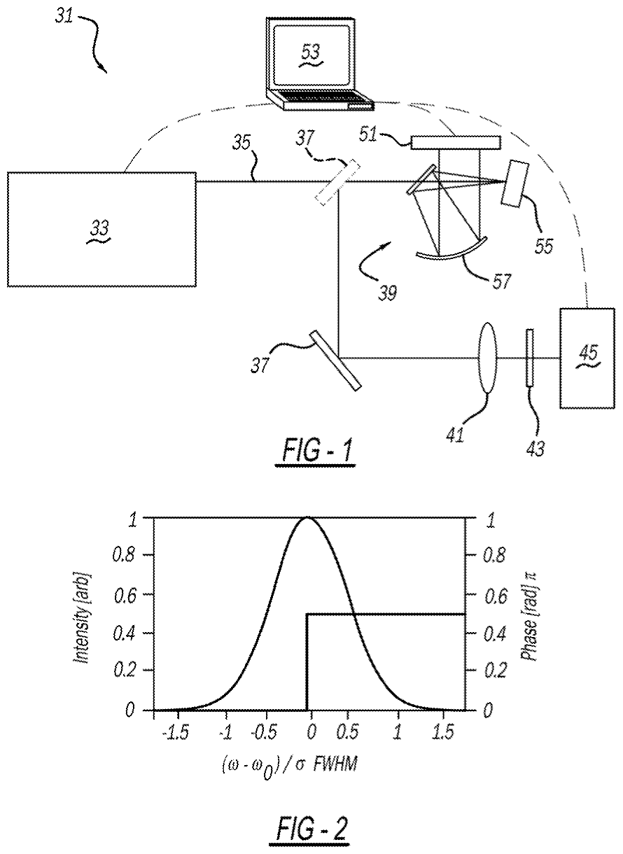

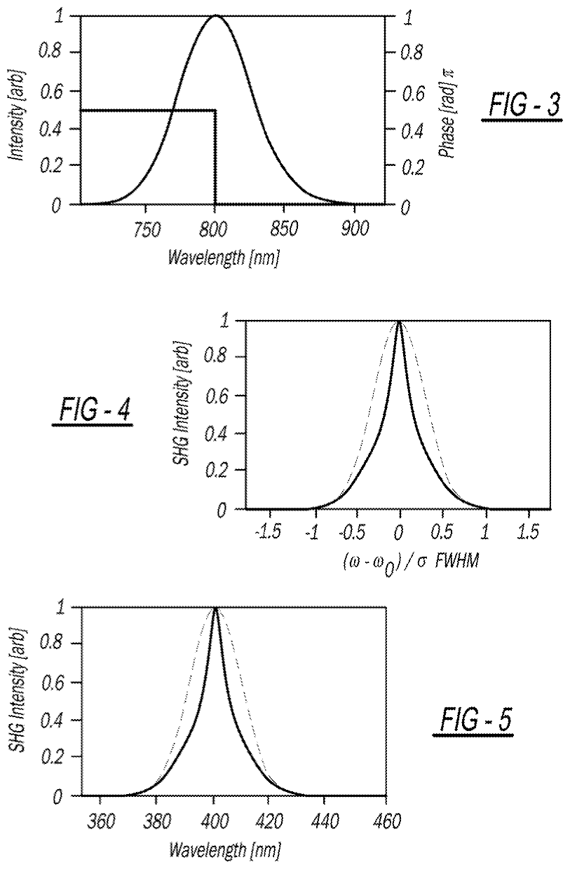

FIGS. 2-5 illustrate the effect of a phase step on a femtosecond laser pulse. More specifically, FIG. 2 shows a spectrum of a 15 fs pulse centered at ω₀ with a +π/2 phase step at the center frequency, while FIG. 3 illustrates a second harmonic spectrum of the same pulse showing how the presence of the +π/2 phase step modifies the spectrum (solid line), compared to the second harmonic spectrum of a TL pulse without the phase step (dashed line). Furthermore, as can be observed in FIG. 4, a spectrum of a 15 fs pulse is centered at 800 nm with a +π/2 phase step at the center frequency, and FIG. 5 represents a second harmonic spectrum of the same pulse showing how the presence of the +π/2 phase step modifies the spectrum (solid line) as compared to the second harmonic spectrum of a TL pulse without the phase step (dashed line).

The present software and method use a π/2 phase step, which is a spectral phase that is 0 for the lower frequency section of the spectrum, and π/2 for the higher frequency section. Similarly, a −π/2 phase step is a spectral phase with 0 for the lower frequency section and −π/2 for the higher frequency section. Furthermore, the transition point between the 0 radian section and the π/2 radian section is called a “step” and may be shifted across the spectrum. A +π/2 spectral phase, along with the spectrum and the resulting second harmonic (“SH”), is shown in FIG. 4 in both frequency and wavelength scales to clarify the definitions used. The equation used for calculating the power spectrum of the second harmonic in terms of a spectral phase is given by:

S(2ω)=|∫_{-∞}^{∞}\sqrt{S(ω+Ω)}\sqrt{S(ω−Ω)}exp[−i{φ(ω°Ω)+φ(ω−Ω)}]dΩ|² .(5)

When a phase step of height a is added to a TL pulse, the exponential term can only take the values 1, e^{jα}, and e^{2iα} or 1,e^{-iα}, and e^{-2iα} for a positive or negative α-step, respectively. When α=π/2, the largest contrast is obtained for the possible values of the exponential term. Further, any phase step n+π/2, where n is an integer, yields maximal SH difference between the positive and negative π/2 steps. Finally, any phase step nπ, where n is an integer, yields no SH difference. Therefore, for the present measurement, positive and negative π/2 phase steps are scanned across the spectrum separately, with the second harmonic being measured at each position.

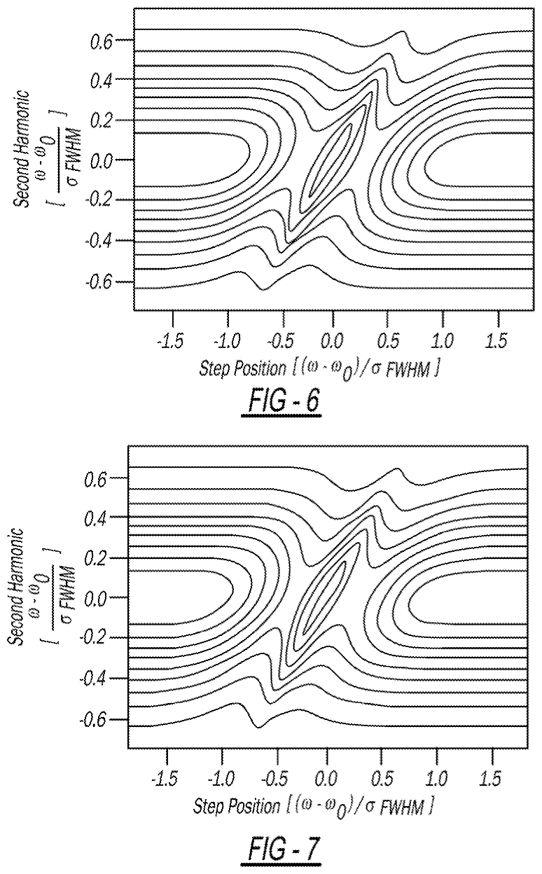

A contour plot that shows the SH spectra as a function of phase step position is shown in FIGS. 6 and 7 for both positive and negative π/2 phase-step scans, respectively. Far from ω=ω₀, the step has little or no influence on the SH spectrum. When the respective ±π/2 steps are scanned over a TL pulse, no difference is observed in the SH spectra at all step positions. However, when the pulse has slight phase distortions such as chirp, high-order dispersion, or any other arbitrary nonlinear function, the positive and negative π/2 steps will yield different contours. This result provides the basis for the present measurement technique.

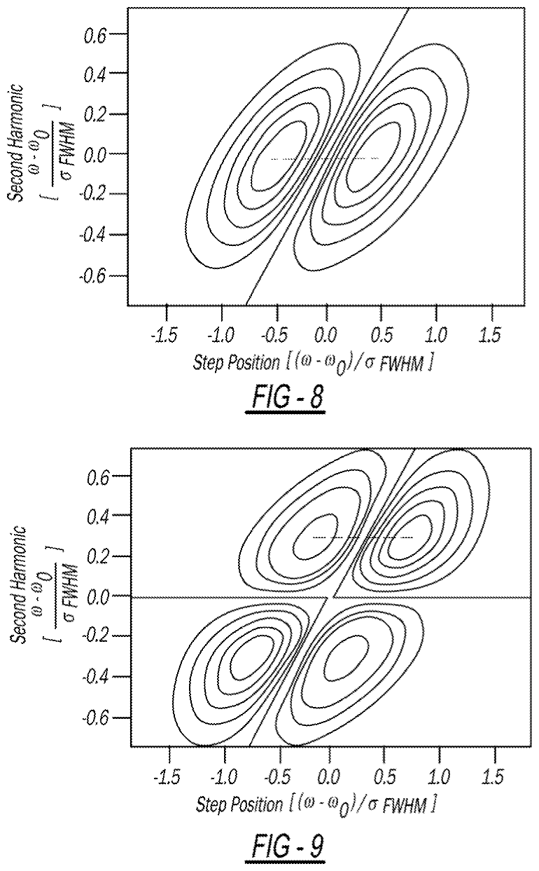

FIG. 8 illustrates the difference between positive and negative contour plots when the 15-fs pulse has 10 fs² of residual chirp. Moreover, FIG. 9 illustrates the difference between positive and negative contour plots when the 15-fs pulse has 300/fs³ of residual TOD. The horizontal dashed lines indicate places convenient for phase measurement. The slight differences in the contour plots resulting from positive and negative π/2 step scans can be more easily visualized by taking the difference between the positive and negative contour plots. Chirp and TOD result in distinct features in the difference contour plot as shown in FIGS. 8 and 9. Chirp leads to a difference contour with a trough (negative) and a peak (positive). Also of note, the sign of the chirp dictates the order of the positive and negative peaks. Third order dispersion leads to a difference contour with four such features, with a node along the central frequency of the second harmonic spectrum. The amplitude of these features in the difference contour correlates with the amount of chirp or TOD, as described below.

The effect of chirp on a femtosecond laser pulse depends on its transform-limited FWHM, T_{TL}, which is given by:

$$\frac{τ}{{τ}_{TL}} = \sqrt{1 + {( \frac{{β}_{2} {g}^{2}}{{τ}_{TL}^{2}} )}^{2}} . \qquad ( 7 )$$

To obtain expressions that are independent of pulse duration, as will be confirmed later, we define \tilde{β}₂ as the reduced chirp magnitude,

\tilde{β}₂≡β₂g²/τ_{TL}² (8)

which simplifies equation (7) to:

$$\frac{τ}{{τ}_{TL}} = \sqrt{1 + {\tilde{β}}_{2}^{2}} . \qquad ( 8 )$$

FIG. 3 illustrates that the SH spectrum is reduced by ½ at the position 0.3σ_{f}, this reduction is symmetric with respect to the center of the spectrum for TL pulses. The presence of positive chirp causes an imbalance, where the attenuation is greater for higher frequencies. The imbalance becomes apparent when plotting the difference between scans obtained with positive and negative phase steps as shown in FIG. 4. The difference ΔS at the center of the SH spectrum as a function of the phase step position, δ, is given by:

ΔS(2ω₀,δ)_{difference}={S(2ω₀,δ)₊−S(2ω₀,−δ)₋}/S(2ω₀,0)_{TL} .(10)

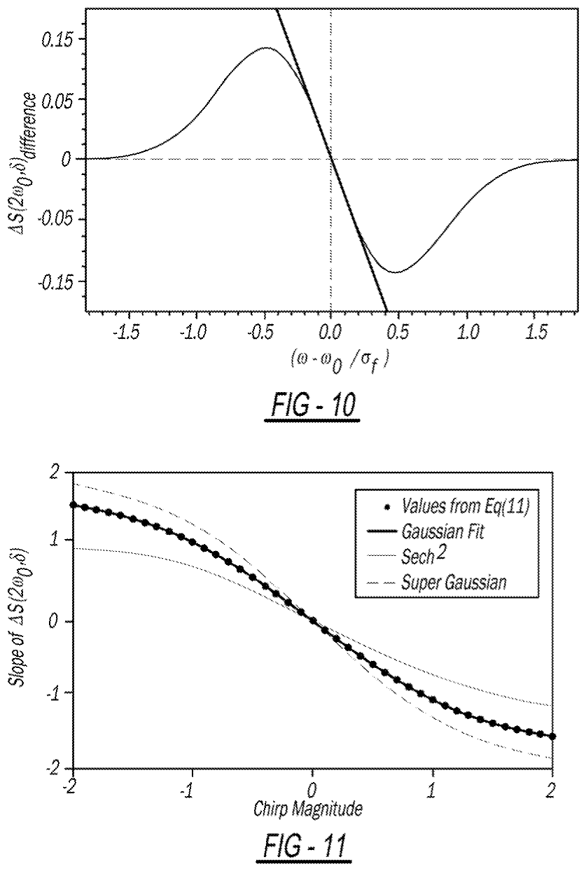

Normalization of the difference by the second harmonic maxima assuming the pulse is TL makes the method independent of pulse duration. The difference defined by equation (10) is plotted for \tilde{β}₂=0.4 in FIG. 10. Thus, the maximum and minimum values are observed, as well as an inflection point where the difference changes sign, centered at δ=(ω−ω₀)/σ_{f}=0.

To quantify the residual chirp on the pulse, the slope near δ(ω−ω₀)=0 provides a good measure of chirp. The slope (shown as the diagonal line crossing the zero intersection) varies sigmoidally as a function of reduced chirp \tilde{β}₂ according to:

bₛₗₒₚₑ(\tilde{β})=A tan h(B\tilde{β}), (11)

where A and B are parameters that define the sigmoidal dependence. When quantifying TOD from a contour plot such as that shown in FIG. 5, S(2ω₀, −σ_{f}/2)_{difference}0, which implies that chirp and TOD enter independently into this expression, and can be measured and corrected independently. Quantification, therefore, seeks the slope of the line that joins the two top features at SH frequency 2(ω−₀)=3σ/10, as is illustrated by the dashed line in FIG. 5. Furthermore, the plot of that line as a function of phase step position looks very similar to that shown for chirp in FIG. 10, except that it is displaced from δ(ω−ω₀)=0 by 3σ/10 for Gaussian pulses. The slope of that line, as a function of the phase step position, varies sigmoidally according to equation (11) as a function of the reduced TOD magnitude, defined as:

\tilde{β}₃≡β₃g³/τ³ .(12)

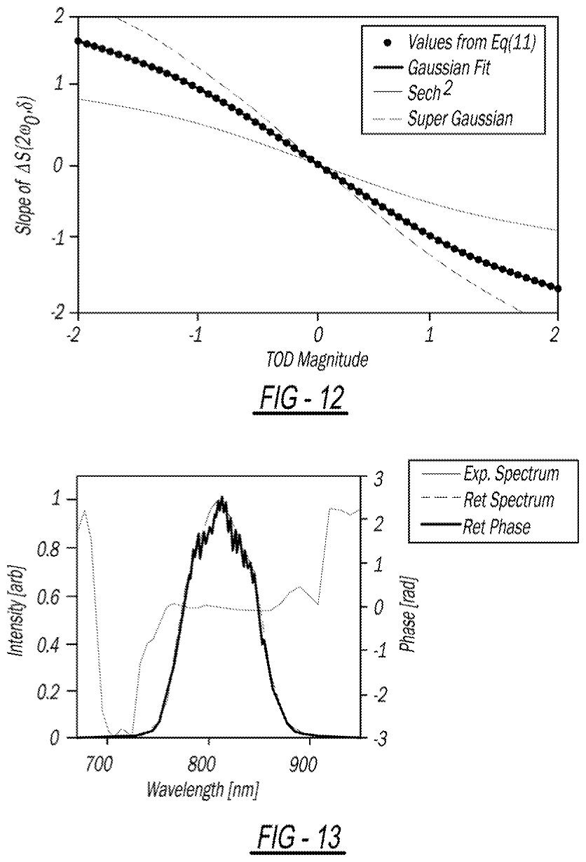

Few ultrafast lasers produce Gaussian pulses, therefore, the present system and method have been extended to other common pulse spectral shapes, such as sech-squared, super-Gaussian, and a skewed spectral shape defined by the sum of two displaced Gaussian functions. The super-Gaussian function has an exponent greater than 2, thus causing the spectrum to be flat-topped. The respective function and parameters used are given in the following Table 1. In all cases, the pulse duration fixed at 15 fs FWHM was maintained. Having defined the different spectra, they are substituted into equation (10) and they behave like the pulses with a Gaussian spectrum, and that their dependence fits on chirp and TOD magnitude using equation (11), as shown in FIGS. 11 and 12. The dots in these graphs correspond to values calculated from the general expression of equation (10), while the lines are fits to the calculated points using equation (11).

For the analysis, the chirp and TOD magnitudes are calculated like those for 15 fs Gaussian pulses. Additionally, the slope is calculated by fitting a line between ±0.2 of the respective bandwidth FWHM, and the TOD slope is calculated by finding the line where the variation is greatest, as represented in FIG. 2, for Gaussian pulses. The sigmoidal parameters depend on the spectral bandwidth of the different pulses. For example, FIGS. 11 and 12 illustrate that the sech-squared spectrum has considerably larger wings than the super-Gaussian spectrum, which is flat-top and has very limited wings. Interestingly, the pulses with the skewed spectrum have essentially the same sigmoidal dependence on chirp and TOD. For experimental spectra that do not conform exactly to these mathematical models, a calibration curve is created by using the shaper to introduce specific amounts of chirp and TOD. Without such calibration, the method will still detect spectral phase distortions, but the accuracy may be decreased.

TABLE 1

| Gaussian | Sech-Squared | Super-Gaussian | Skewed |
|---|---|---|---|
| S(ω) = e^{-[τ(ω-ω}^{₀}^{)/g]}^{²} | $S ( ω ) = {Sech [ \frac{τ ( ω - {ω}_{0} ) π}{4 Ln ( 1 + \sqrt{2} )} ]}^{2}$ | S(ω) = e^{-[τAbs[(ω-ω}^{₀}^{]/2.126]}^{³} | S(ω) = 0.94e^{-[τ(ω-ω}^{₀}^{+0.04)/1.26 g]}^{²} + 0.33e^{-[τ(ω-ω}^{₀}^{-0.08)/1.26 g]}^{²} |
| τ_{f} = 15 fs | τ_{f} = 15 fs | τ_{f} = 15 fs | τ_{f} = 15 fs |
| σ_{f} = g²/τ_{f} | ${σ}_{f} = \frac{{[ 4 Ln ( 1 + \sqrt{2} ) ]}^{2}}{2 {πτ}_{f}}$ | σ_{f} = 0.25 fs⁻¹ | σ_{f} = 0.185 fs⁻¹ |

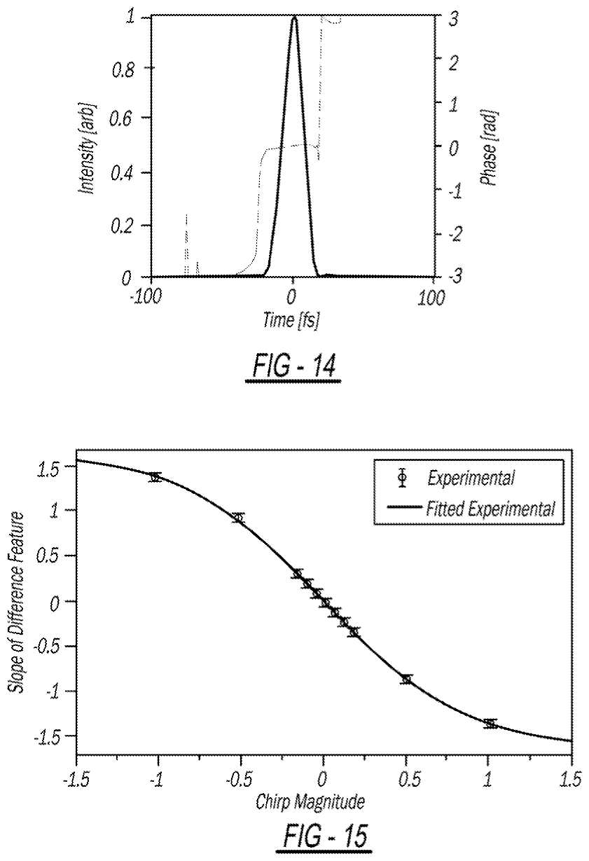

Experiments can be carried out using the present laser system of FIG. 1 including a titanium sapphire oscillator (such as one from Vitara, Coherent), operating at 80 MHz, capable of producing 15 fs pulses centered ˜810 nm; the expected results of which may be observed in FIGS. 13 and 14. The output of the laser is sent to a pulse shaper (such as the MIIPS® Box 640, which may be obtained from Biophotonic Solutions Inc. and IPG Photonics) and the output is then doubled in a 0.1 mm BBO (β-BaB₂O₄) crystal. The software should be used for confirming spectral alignment and calibration of the pulse shaper. The SH spectrum is collected with a compact spectrometer and for the measurements, MIIPS® device and procedures are employed for pulse compression and obtained near TL pulses.

The experimental calibration parameters for chirp and TOD magnitude which do not conform to a standard function are performed as follows. The π/2 step is scanned across the spectrum while recording the SH spectrum and writing it to a matrix, and the process is repeated for the negative π/2 step; the difference between the two matrices is plotted as the contour map of FIGS. 6-9. Since this initial contour plot cannot be quantified yet, it is treated as background. Next, the pulse shaper introduces a series of chirp values from which the contour maps are defined by equation (10), which are analyzed after subtracting the background contour plot. From the difference values near 2ω₀ and δ(ω−ω₀)=(2±1)σ/10, shown as the dashed line in FIG. 4, the slope for each chirp value is obtained. Slopes are subsequently fit using equation (11) to obtain the sigmoidal function for chirp magnitude. The process is repeated to calibrate TOD measurements and the slope measurements are made at the position where a pair of features reaches their maximum and minimum values as depicted in FIG. 5.

Having obtained the calibration curves, spectral phase measurements are performed without subtracting the background contour. Furthermore, the pulse shaper is used to first eliminate chirp by entering a complementary chirp value to what is measured and then measuring and eliminating TOD to obtain TL pulses. The total phase distortion compensated corresponds to an accurate spectral phase measurement at the location of the SH crystal. Stated in a different way, the phase added as complementary during the measurement is the phase that compresses the pulses to their transform limit. When the present method is used for pulse characterization, the complementary phase is complementary of the phase dispersion of the input pulses, provided the pulse shaper is dispersion free. Having eliminated SOD chirp and TOD, the pulses are now TL, with single-digit milliradian spectral phase deviation.

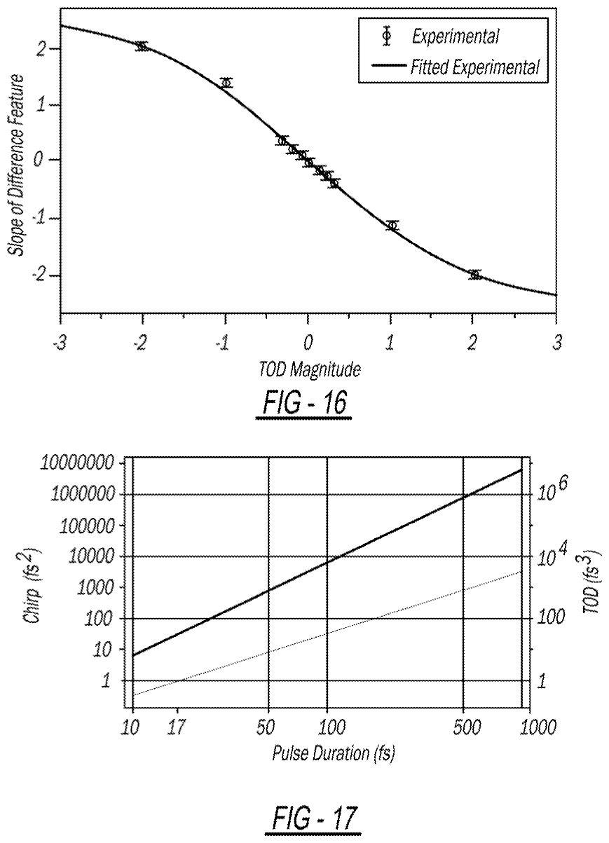

The experimental calibration curves of FIGS. 15 and 16 are obtained for chirp and TOD values ranging from −1.5 to 1.5 for \tilde{β}₂ and −3 to 3 for \tilde{β}₃. The dots in these graphs correspond to expected measured values, while the line corresponds to equation (11) without experimental adjustment, respectively. Error bars are shown for ±1σ error.

The data in FIGS. 15 and 16 reproduce the theoretically predicted sigmoidal function. The sigmoidal function is parameterized into the form shown in equation (11). Experimental data may be fitted to this equation, although the parameters will differ from theoretical calculations due to a different spectral shape in the experimental setting. A comparison of the sigmoidal fit parameters obtained experimentally with those obtained by simulation using the experimentally obtained spectrum and equation (10), as provided in Table 2, with a 95% confidence interval. Once the experimental parameters have been acquired, the method can be used to measure small chirp or TOD values using the calibrated sigmoidal relationships as shown below.

TABLE 2

| | Theory | |
|---|---|---|
| | (Experimental Spectrum) | Experimental |
| A (Chirp) | −3.181 | −3.31 ± 0.10 |
| B (Chirp) | 1.230 | 1.31 ± 0.11 |
| A (TOD) | −2.314 | −2.61 ± 0.57 |
| B (TOD) | 0.403 | 0.51 ± 0.17 |

Having confirmed the theory, the precision of the method is quantified. The first benchmark test is a measurement of the GVD of a 1-mm fused silica window. The laser's phase is corrected with MIIPS and this method, then the fused silica window is placed in the beam path. The π/2 steps are scanned, and the chirp is found as above from the difference contour. This method yields an expected GVD value of 36.18±0.548 fs²/mm, which agrees well with 36.162 fs²/mm using Sellmeier's formula and the optical constants for fused silica, and 36.2±0.5 fs²/mm MIIPS®. The expected value with white-light interferometry 35.92±0.05 fs²/mm was less accurate.

This method is precise enough to measure very small chirp values such as the dispersion introduced by air. The group delay dispersion of air at 800 nm is measured under identical altitude and temperature conditions to be 20.05±0.05 fs²/m. To test the method, the path length of the laser pulses is varied as they arrive at the SH crystal where they are frequency doubled. The amount of chirp is measured each time that the path length is increased by 0.254 m. ˜5.08 fs² additional dispersion is expected.

The precision with which the spectral phase can be measured depends on the bandwidth of the pulses, and hence their TL pulse duration. For chirp, the dependence on pulse duration is quadratic and for TOD is cubic. The expected data shown here is pulse duration independent because it is given in terms of \tilde{β}₂ and \tilde{β}₃, from equations (8) and (12). Thereafter, the precision expected is translated to radians. Chirp and TOD spectral phase functions reach their maximum value at half of the FWHM. Therefore, the maximum phase value reached at σ_{f}/2

$$φ ( {σ}_{f} / 2 ) = \frac{{β}_{2}}{2 !} {( {σ}_{f} / 2 )}^{2} = \frac{{\tilde{β}}_{2} {τ}^{2}}{2 ! {g}^{2}} {( {g}^{2} / 2 τ )}^{2} = {\tilde{β}}_{2} {g}^{2} / 2 ! {2}^{2} , \qquad ( 14 )$$

for chirp and

$$φ ( {σ}_{f} / 2 ) = \frac{{β}_{3}}{3 !} {( {σ}_{f} / 2 )}^{3} = \frac{{\tilde{β}}_{3} {τ}^{3}}{3 ! {g}^{3}} {( {g}^{2} / 2 τ )}^{3} = {\tilde{β}}_{3} {g}^{3} / 3 ! {2}^{2} , \qquad ( 15 )$$

for TOD. Therefore, having determined the precision with which \tilde{β}₂ and \tilde{β}₃ are measured, the accuracy of the method in terms of milliradians is determined, and based on equations (13) and (14), the result is independent of pulse duration. An error analysis in the expected measurements determines the precision to be \tilde{β}₂=±0.009 and \tilde{β}₃=±0.029. Moreover, the precision of this method in milliradians is obtained using equations (13) and (14) and is 3.1 and 1.7 mrad, respectively. Based on these values, minimum measurable chirp and TOD for pulse durations ranging from 10 fs to 1 ps, are extrapolated assuming the pulse shaper is configured for the bandwidth of the pulses. The expected results are plotted in FIG. 17. Advantageously, for the 17 fs pulses, there is a sensitivity to 1 fs² of chirp and 32 fs³.

In summary, the present system and method measures single-digit milliradian phase variations on pre-compressed femtosecond pulses with the use of the present π/2 scan method and software instructions. The variations illustrated include chirp and TOD. The method can measure and compress phase variations that range from second to eight-order dispersion including arbitrary phase distortions as described in the software instructions. The present technique can be performed in addition to commercially available pulse shaper-based compression systems to reach levels of accuracy previously unreachable. This accuracy may find utility in areas of measurements of physical constants to metrology to the correction of experimental aberrations. When the method is performed with a zero-dispersion pulse shaper, the results provide highly accurate pulse characterization. Beneficially, milliradian precision of the spectral phase is made easy with the present method and can be streamlined into one system, reducing the highly skilled labor otherwise needed to find the second and third order dispersion terms. Furthermore, the present system and method allow for the generation of TL pulses with unprecedented accuracy as the evolution of ultrafast lasers continues. Use of this is especially advantageous in strong field laser-matter interactions, where minimal amounts of chirp can change the sign of enhancements observed via pulse shaping.

While various constructions of the present method and system have been disclosed, it should be appreciated that other variations can be employed. For example, additional, fewer or alternate optical components can be used although certain benefits may not be realized. More or less software instruction steps may also be employed, for example instructions introduced to reduce noise in the detected signal. Moreover, the claims may be combined in any combination of overlapping multiple dependencies.

Other modifications to the present method and system may still fall within the scope and spirit of the present invention.

1. A method of using a laser system, the method comprising:
(a) emitting laser pulses each having a duration less than 1000 femtoseconds, the pulses having second or greater order dispersion;
(b) shaping the laser pulses; and
(c) measuring less than 10 milliradian phase variations on the pulses by a programmable controller with the use of π/2 scan of a spectral phase of at least one of the laser pulses, regardless of whether the pulse is asymmetric.

2. The method of claim 1, further comprising automatically determining calibration parameters for chirp which do not conform to a standard function using the programmable controller and pulse shaper by performing the steps comprising:
(d) recording a second harmonic spectrum while conducting the π/2 scan across the spectral phase;
(e) repeating the recording and scanning for a negative π/2 step;
(f) plotting a difference between positive and negative data from the recordings as the contour map, and treating the plotted difference as background;
(g) after the plotting, using the pulse shaper to introduce a series of chirp values from which the contour maps are defined by equation (10), which are analyzed after subtracting the background;
(h) obtaining a slope for each chirp value from difference values near 2ω₀ and δ(ω−ω₀)=(2±1)σ/10;
(i) after the obtaining, fitting slopes using equation (11) to obtain a sigmoidal function for chirp magnitude.

3. The method of claim 2, further comprising repeating steps (d)-(i) to have the programmable controller automatically calibrate TOD measurements.

4. The method of claim 1, further comprising automatically determining calibration parameters for TOD magnitude which do not conform to a standard function using the programmable controller and pulse shaper by performing the steps comprising: (d) recording a second harmonic spectrum while conducting the π/2 scan across the spectral phase;
(e) repeating the recording and scanning for a negative π/2 step;
(f) plotting a difference between positive and negative data from the recordings as the contour map, and treating the plotted difference as background;
(g) eliminating chirp with the pulse shaper by entering a complementary chirp value to what is measured and then measuring and eliminating TOD to obtain TL pulses;
(h) causing a total phase distortion of at least some of the pulses to be compensated an amount corresponding to an accurate spectral phase measurement at a location of a second harmonic crystal, such that when used for pulse characterization, a complementary phase is complementary of a phase dispersion of input pulses, when the pulse shaper is dispersion free; and
(i) causing the pulses to be transform limited with the <10 milliradian spectral phase deviation.

5. The method of claim 1, further comprising shaping the pulses with a programmably adaptive pulse shaper to scan a sharp phase step to reveal residual amounts of spectral dispersion including chirp and third-order dispersion, with an accuracy within 0.02 fs², and a precision of 1 fs².

6. The method of claim 1, further comprising using software instructions within the programmable controller to automatically measure very small chirp values with a group delay dispersion within 800 nm and 20.05±0.05 fs²/m using the pulse shaper which is a zero-dispersion pulse shaper, and the programmable controller providing highly accurate pulse characterization of the pulses within 0.02 fs².

7. The method of claim 1, further comprising:
emitting the pulses from a femtosecond seed laser, including an amplifier and an oscillator;
modifying the pulses with a pulse shaper automatically and actively controlled by the programmable controller, the pulse shaper being programmably adaptive and comprising at least one of: a spatial light modulator or a curved mirror;
measuring phase variations of at least some of the pulses with programmed software instructions operating in the programmable controller;
modifying the pulses with a second harmonic crystal;
automatically measuring and correcting distortions of at least some of the pulses with the π/2 scan; and
the pulses each having a duration equal to or less than 15 fs.

8. A method of using a laser system, the method comprising:
(a) emitting laser pulses each having second or greater order dispersion;
(b) shaping the laser pulses with an active and programmable pulse shaper;
(c) eliminating chirp with the pulse shaper by entering a complementary chirp value to what is measured and then measuring and eliminating TOD to obtain transform limited pulses; and
(d) operating software instructions within a programmable controller to measure less than 10 milliradian phase variations on the pulses by scanning positive and negative π/2 values of a spectral phase of at least one of the laser pulses.

9. The method of claim 8, further comprising automatically determining calibration parameters for the chirp using the programmable controller and the pulse shaper by performing the steps comprising:
(e) recording a second harmonic spectrum while conducting the π/2 scans across the spectral phase;
(f) determining a difference between data from the positive and negative π/2 scans;
(g) after the determination, using the pulse shaper to introduce a series of chirp values from which contour maps are generated, which are analyzed after subtracting the determined difference;
(h) obtaining a slope for each chirp value from difference values near 2ω₀ and δ(ω−ω₀)=(2±1)σ/10; and
(i) after the obtaining, fitting slopes to obtain a sigmoidal function for chirp magnitude.

10. The method of claim 8, further comprising automatically determining calibration parameters for TOD magnitude using the programmable controller and the pulse shaper by performing the steps comprising:
(e) causing a total phase distortion of at least some of the pulses to be compensated an amount corresponding to an accurate spectral phase measurement at a location of a second harmonic crystal, such that when used for pulse characterization, a complementary phase is complementary of a phase dispersion of input pulses; and
(f) causing the pulses to be transform limited with the <10 milliradian spectral phase deviation.

11. The method of claim 8, further comprising detecting second harmonic data from a spectrometer, scanning chirp values in the pulses from minus to plus, finding a maximum chirp value from the scanned chirp values and entering a negative chirp value in at least some of the pulses via the pulse shaper.

12. The method of claim 11, further comprising scanning the TOD from minus to plus, finding a maximum TOD value from the scanned TOD and entering a negative TOD value in at least some of the pulses via the pulse shaper.

13. The method of claim 8, further comprising measuring a chirp magnitude using the software instructions and automatically introducing the complementary chirp phase in at least some of the pulses with the pule shaper to eliminate a measured chirp magnitude.

14. A laser system comprising:
(a) laser pulses each having second or greater order dispersion;
(b) shaping the laser pulses with an active pulse shaper comprising at least one of: a spatial light modulator or a curved mirror;
(c) a programmable controller operably running software stored on non-transient memory therein, the software comprising:
programmed instructions configured to eliminate chirp by causing the pulse shaper to enter a complementary chirp value to what is measured and then measuring and eliminating TOD to obtain transform limited pulses; and
programmed instructions configured to measure phase variations on the pulses by scanning positive and negative π/2 values of a spectral phase of at least some of the pulses.

15. The laser system of claim 14, further comprising programmed instructions configured to automatically determine calibration parameters for the chirp by operably:
determining a second harmonic spectrum while conducting the π/2 scans across the spectral phase;
determining a difference between data from the positive and negative π/2 scans;
causing the pulse shaper to introduce a series of chirp values from which contour maps are generated, and the determined difference is subtracted therefrom;
obtaining a slope for some of the chirp values; and
fitting slopes to obtain a sigmoidal function for chirp magnitude.

16. The laser system of claim 14, further comprising programmed instructions configured to cause at least some of the pulses to be transform limited with <10 milliradian spectral phase deviation.

17. The laser system of claim 14, further comprising programmed instructions configured to: detect second harmonic data from a spectrometer, scan chirp values in the pulses from minus to plus, find a maximum chirp value from the scanned chirp values and enter a negative chirp value in at least some of the pulses via the pulse shaper.

18. The laser system of claim 14, further comprising programmed instructions configured to scan TOD values from minus to plus, find a maximum TOD value from the scanned TOD values and enter a negative TOD value in at least some of the pulses via the pulse shaper.

19. The laser system of claim 14, further comprising programmed instructions configured to scan the positive and negative π/2 values across a phase mask of the pulse shaper while collecting second harmonic spectra.

20. The laser system of claim 19, further comprising programmed instructions configured to calculate arbitrary phase information and introduce a complementary arbitrary phase via the pulse shaper to automatically eliminate the arbitrary phase from at least some of the pulses.
